(19) United States
(12) Patent Application Publication
(10) Pub. No.: US 2015/0255704 A1
(43) Pub. Date: Sep. 10, 2015

(54) PIEZOELECTRIC ELEMENT AND PIEZOELECTRIC VIBRATOR HAVING THE SAME

(71) Applicant: SAMSUNG ELECTRO-MECHANICS CO., LTD., Suwon-Si (KR)

(72) Inventors: Boum-Seock KIM, Suwon-Si (KR); Kyung-Lock KIM, Suwon-Si (KR); Hui-Sun PARK, Suwon-Si (KR); Jung-Wook SEO, Suwon-Si (KR)

(21) Appl. No.: 14/493,148

(22) Filed: Sep. 22, 2014

(30) Foreign Application Priority Data
Mar. 10, 2014 (KR) 10-2014-0027942
May 14, 2014 (KR) 10-2014-0057711

(51) Int. Cl. H01L 41/083; H01L 41/187; H01L 41/047; H01L 41/053

(52) U.S. Cl. CPC H01L 41/0838; H01L 41/0533; H01L 41/187; H01L 41/0477; H01L 41/0474

(57) ABSTRACT

A piezoelectric element and a piezoelectric vibrator having the same are disclosed. A piezoelectric element according to the present invention includes: a plurality of ceramic piezoelectric layers configured to contract and expand according to supply of electric power; an electrode pattern constituted with electrodes laminated alternately with the plurality of ceramic piezoelectric layers; and a flexible layer formed on a surface of an upper-most electrode of the electrode pattern so as to protect the upper-most electrode and configured to prevent a crack from occurring by contracting and expanding according to contraction and expansion of the ceramic piezoelectric layers.

### CROSS-REFERENCE TO RELATED APPLICATIONS

This application claims the benefit of Korean Patent Application Nos. 10-2014-0027942 and 10-2014-0057711, filed with the Korean Intellectual Property Office on Mar. 10, 2014 and May 14, 2014, respectively, the disclosure of which is incorporated herein by reference in their entirety.

### BACKGROUND

1. Technical Field

The present invention relates to a piezoelectric element and a piezoelectric element having the same.

2. Background Art

Touch panels, touch keyboards and the like can be installed on electronic devices to provide vibrations to user's fingertips when letters or drawings are inputted. Such a function of providing a tactile feedback for inputting letters or drawings is referred to as a haptic function.

A haptic device utilizes a structure in which vibrations are transferred to a user by having the vibrations provided to a touch panel by a vibration generating means, such as a piezoelectric actuator.

Piezoelectric ceramics can be used for piezoelectric actuators. When the piezoelectric ceramics vibrate according to the piezoelectric properties thereof, the piezoelectric ceramics may be cracked, lowering the reliability of the piezoelectric actuators.

Conventionally, the piezoelectric ceramics have been prevented from cracking by using silicon (Si) and the like as a secondary component of the composition for the piezoelectric ceramics. This was an attempt to solve the problem not by changing the configuration of the piezoelectric ceramics but by changing the materials for the piezoelectric ceramics.

The related art of the present invention is disclosed in Korea Patent Publication No. 2002-0016592 (PIEZOELECTRIC CERAMIC COMPOSITION AND PIEZOELECTRIC ELEMENT; laid open on Mar. 4, 2002).

### SUMMARY

The present invention provides a piezoelectric element and a piezoelectric vibrator that can reduce occurrence of cracks in a top portion of the piezoelectric element.

An aspect of the present invention provides a piezoelectric vibrator, which includes: a vibrating plate; and a piezoelectric element coupled to an upper surface of the vibrating plate and configured to vibrate the vibrating plate. The piezoelectric element includes: a plurality of ceramic piezoelectric layers configured to contract and expand according to supply of electric power; an electrode pattern constituted with electrodes laminated alternately with the plurality of ceramic piezoelectric layers; and a flexible layer formed on a surface of an upper-most electrode of the electrode pattern.

A thickness of the flexible layer can be greater than or equal to ¼ and smaller or equal to ⅓ of a thickness of the piezoelectric element.

The flexible layer can be made of a material comprising resin.

The piezoelectric vibrator can further include a ceramic cover layer coupled to a lower portion of a lower-most layer of the plurality of ceramic piezoelectric layers and covering a lower-most electrode of the electrode pattern.

The piezoelectric vibrator can further include an adhesive material interposed between the piezoelectric element and the vibrating plate.

The plurality of ceramic piezoelectric layers can further include a PNN-PZT ceramic material and a sintering aid including at least one of NiO, CuO, ZnO and PbO.

The electrodes of the electrode pattern can include at least one of Cu, Ag and Pd.

The piezoelectric element can further include a via formed by penetrating the plurality of ceramic piezoelectric layers in order to electrically connect the electrodes of the electrode pattern, and further include a terminal electrically connected with the electrode pattern and formed to be exposed on a surface of an upper-most layer of the plurality of ceramic piezoelectric layers.

The via and the terminal can be each provided in two pairs that are electrically connected with the electrodes.

The piezoelectric element can further include an external electrode formed on lateral surfaces of the plurality of ceramic piezoelectric layers so as to electrically connect the electrodes of the electrode pattern.

Another aspect of the present invention provides a piezoelectric element, which includes: a plurality of ceramic piezoelectric layers configured to contract and expand according to supply of electric power; an electrode pattern constituted with electrodes laminated alternately with the plurality of ceramic piezoelectric layers; and a flexible layer formed on a surface of an upper-most electrode of the electrode pattern.

### BRIEF DESCRIPTION OF THE DRAWINGS

FIG. 1 shows a piezoelectric vibrator in accordance with an embodiment of the present invention.

FIG. 2 and FIG. 3 show a piezoelectric element in accordance with an embodiment of the present invention.

FIG. 4 and FIG. 5 show vibrations of the piezoelectric vibrator in accordance with an embodiment of the present invention.

FIG. 6 shows a piezoelectric vibrator in accordance with another embodiment of the present invention.

FIG. 7 shows a piezoelectric element in accordance with another embodiment of the present invention.

FIG. 8 shows a piezoelectric vibrator in accordance with yet another embodiment of the present invention.

### DETAILED DESCRIPTION

Hereinafter, certain embodiments of a piezoelectric element and a piezoelectric vibrator in accordance with the present invention will be described in detail with reference to the accompanying drawings. In describing certain embodiments of the present invention with reference to the accompanying drawings, any identical or corresponding elements will be assigned with same reference numerals, and their redundant description will not be provided.

Terms such as “first” and “second” can be used in describing various elements, but the above elements shall not be restricted to the above terms. The above terms are used only to distinguish one element from the other.

When one element is described as being “coupled” or “connected” to another element, it shall be construed as not only being in physical contact with the other element but also as possibly having a third element interposed therebetween and each of the one element and the other element being in contact with the third element.

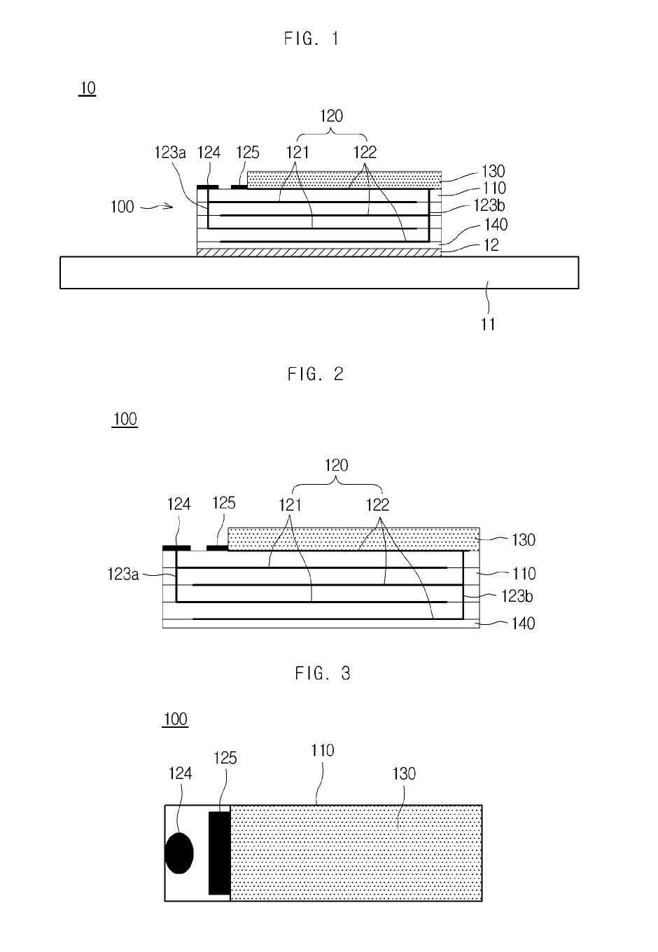

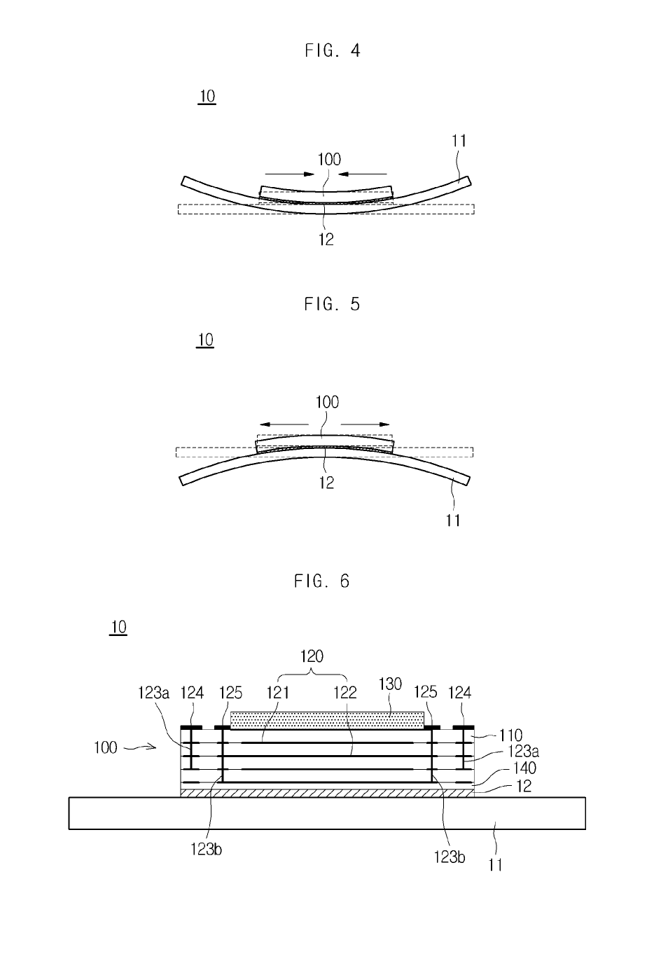

FIG. 1 shows a piezoelectric vibrator in accordance with an embodiment of the present invention. FIG. 2 and FIG. 3 show a piezoelectric element in accordance with an embodiment of the present invention. FIG. 4 and FIG. 5 show vibrations of the piezoelectric vibrator in accordance with an embodiment of the present invention.

Referring to FIG. 1, a piezoelectric vibrator 10 can include a vibrating plate 11 and a piezoelectric element 100 and can further include an adhesive material 12. Moreover, referring to FIG. 2 and FIG. 3, the piezoelectric element 100 can include a plurality of ceramic piezoelectric layers 110, an electrode pattern 120 and a flexible layer 130 and can further include a ceramic cover layer 140. Moreover, the piezoelectric element 100 can further include a via 123 and terminals 124, 125.

The vibrating plate 11 is a plate designed to vibrate up and down according to movement of the piezoelectric element 100 and can be made of steel or stainless steel (SUS). The vibrating plate 11 can perform a function of transferring vibrations to a touch panel, an image display unit, HPP or the like, and the transferred vibrations are realized in a haptic technology.

The piezoelectric element 100 is an element that is formed on an upper surface of the vibrating plate 11 and vibrates the vibrating plate 11. The piezoelectric vibrator 10 can further include the adhesive material 12, and the piezoelectric element 100 can be readily attached to the vibrating plate 11 by the adhesive material 12. Moreover, the adhesive material 12 can insulate the piezoelectric element 100 from the vibrating plate 11.

As shown in FIG. 4 and FIG. 5, the piezoelectric element 100 can contract and expand in lengthwise directions when electric power is supplied, and the vibrating plate 11 coupled to the piezoelectric element 100 can vibrate up and down accordingly.

The ceramic piezoelectric layer 110 is a layer that has piezoelectric properties, and one ceramic piezoelectric layer 110 can have a thickness of about 80 um. The ceramic piezoelectric layer 110 can include a PNN-PZT ceramic material. That is, the ceramic piezoelectric layer 110 can be made of ceramic that is constituted with a solid solution made of Pb, Ni and Nb and a solid solution made of Pb, Zr and Ti. In such a case, the ceramic piezoelectric layer 110 can be made of ceramic having the following formula as a main component.

x[Pb{Zr_{y}Ti_{(1-y)}O}₃]-(1−x)[Pb(Ni_{z}Nb_{(1-z)}O₃]

Here, x, y and z are constants, in which x can be 0.8, and y can be 0.44, and z can be ⅓.

Moreover, the ceramic piezoelectric layer 110 can further include a secondary component that is used for a sintering aid. The sintering aid used as the secondary component can include at least one of NiO, CuO, ZnO and PbO. The sintering aid can be added in the ratio of 1.6 wt % of the whole composition of the ceramic piezoelectric layer 110. With the sintering aid, a sintered density of the ceramic piezoelectric layer 110 can be increased.

When electric power is supplied to the electrode pattern 120 to apply voltage to the piezoelectric element 100, an electric field is formed between two poles (+, −) in the ceramic piezoelectric layer 110, and the structure of the ceramic piezoelectric layer 110 is changed by dipole occurred within the ceramic piezoelectric layer 110, allowing the ceramic piezoelectric layer 110 to contract and expand.

The ceramic piezoelectric layer 110 can be provided in plurality, and the plurality of ceramic piezoelectric layers 110 can allow greater piezoelectric characteristics to be realized with a same voltage.

The electrode pattern 120 is constituted with electrodes 121, 122 that are formed orthogonally to the ceramic piezoelectric layer 110. That is, the electrodes 121, 122 constituting the electrode pattern 120 can be formed in between the plurality of ceramic piezoelectric layers 110 and on outside surfaces of the lower-most and upper-most ceramic piezoelectric layers 110.

The electrodes can be divided into first electrodes 121 and second electrodes 122. The first electrodes 121 and the second electrodes 122 can have different polarities from each other. For example, in the case where the first electrodes 121 have a (+) polarity, the second electrodes 122 can have a (−) polarity. The first electrodes 121 and the second electrodes 122 can be alternately laminated side by side.

Here, being “side by side” means that each electrode is parallel with the ceramic piezoelectric layer 110. Meanwhile, the reason why the first electrodes 121 and the second electrodes 122 alternate with each other is that the electric field can be formed within the ceramic piezoelectric layer 110 only if the electrodes alternate with each other.

For example, in a four-layer structure of piezoelectric element 100, lamination can be made in the order of, from a lower portion to an upper portion, a (−) electrode, a first ceramic piezoelectric layer, a (+) electrode, a second ceramic piezoelectric layer, a (−) electrode, a third ceramic piezoelectric layer, a (+) electrode, a fourth ceramic piezoelectric layer and a (−) electrode. Here, “lower portion” refers to a side that is toward the vibrating plate 11, and “upper portion” refers to a side that is away from the vibrating plate 11.

The electrodes of the electrode pattern 120 can be made of electrode paste that includes at least one of copper (Cu), silver (Ag) and palladium (Pd). The electrode paste becomes the electrodes 121, 122 by being printed and then fired. For instance, the electrode can be formed from an electrode paste made of 100% silver or from an electrode paste made of a mixture of silver and palladium. In the latter case, the mixing ration of silver and palladium can be greater than or equal to 7/3 and smaller than or equal to 9.5/0.5 (silver/palladium).

The electrode paste can be printed on one surface or both surfaces of each of the plurality of ceramic piezoelectric layers 110, and accordingly the electrodes are formed in between the plurality of ceramic piezoelectric layers 110 and on the outside surfaces of the upper-most and lower most ceramic piezoelectric layers 110. A printed area of the electrode past can be smaller than an area of one surface of a single ceramic piezoelectric layer 110.

As described above, in the case where the piezoelectric element 100 is configured with four ceramic piezoelectric layers 110, the electrode pattern 120 can be configured with two first electrodes 121 and three second electrodes 122. Here, the first electrodes 121 are all formed in between the ceramic piezoelectric layers 110 and thus are not exposed, but some of the second electrodes 122 are formed on outside surfaces of the upper-most and the lower-most ceramic piezoelectric layers 110, respectively, and thus can be exposed. The second electrode 122 positioned on the lower-most layer faces an upper surface of the vibrating plate 11.

If, meanwhile, the piezoelectric element 100 is configured with an odd number of ceramic piezoelectric layers 110, there can be a same number of first electrodes 121 and second electrodes 122, and the first electrode 121 that is positioned on the upper-most layer and the second electrode 122 that is positioned on the lower-most layer can be exposed.

Hereinafter, the electrode formed on the outside surface of the upper-most ceramic piezoelectric layer 110 will be referred to as “upper-most electrode,” and the electrode formed on the outside surface of the lower-most ceramic piezoelectric layer 110 will be referred to as “lower-most electrode.”

The flexible layer 130, which is formed on a surface of the upper-most electrode of the electrode pattern 120, can contract and expand according to contraction and expansion of the ceramic piezoelectric layer 110. By contracting and expanding according to the contraction and expansion of the ceramic piezoelectric layer 110, the flexible layer 130 itself is not cracked.

The flexible layer 130 can be made of a highly flexible material, particularly, a material containing resin. Here, the resin can include at least one of epoxy, silicon and urethane.

A thickness of the flexible layer 130 can be greater than or equal to ¼ and smaller than or equal to ⅓ of a total thickness of the plurality of ceramic piezoelectric layers 110. If the thickness of the flexible layer 130 were smaller than 1/4 of the total thickness of the plurality of ceramic piezoelectric layers 110, the flexible layer 1300 would not be able to perform the function of contraction and expansion for preventing a crack, and if the thickness of the flexible layer 130 were greater than ⅓ of the total thickness of the plurality of ceramic piezoelectric layers 110, the piezoelectric element 100 could be too thick. For example, four of the ceramic piezoelectric layers 110, each having a thickness of 80 um, can be laminated with one another to form a total thickness of 320 um for the ceramic piezoelectric layers 110, and a thickness of the flexible layer 130 can be 100 um. In such a case, a thickness ratio of the flexible layer 130 to the plurality of ceramic piezoelectric layers 110 becomes approximately 0.31.

As illustrated in FIG. 4 and FIG. 5, when the piezoelectric element 100 contracts and expands, the piezoelectric vibrator 10 vibrates. In such a case, a point where stress is zero in the piezoelectric vibrator 10 is near a bottom at a center of the piezoelectric element 100.

In other words, the piezoelectric element 100 has the largest stress at an upper-most portion thereof, and thus the upper-most portion of the piezoelectric element 100 is more likely to have a crack occurred therein when the piezoelectric vibrator 10 vibrates. Moreover, since the crack occurred at a portion of the piezoelectric element 100 can be spread to a crack all over the piezoelectric element 100, jeopardizing the reliability of the piezoelectric element 100.

In case an upper-most portion cover for protecting the upper-most electrode is made of ceramic, the upper-most portion cover has no piezoelectric characteristics therein because there is no electric field formed within the upper-most cover. Moreover, since ceramic has little elasticity or flexibility, a crack can be easily occurred in the upper-most portion cover when the piezoelectric element 100 vibrates.

On the contrary, in the case of an embodiment of the present invention in which the upper-most portion cover for protecting the upper-most electrode is not made of ceramic but configured with the above-described flexible layer 130, the flexible layer 130 is flexible enough to contract and expand with the ceramic piezoelectric layer 110, and thus no crack is occurred in the flexible layer 130 when the ceramic piezoelectric layer 110 contracts and expands. As long as no crack is occurred in the flexible layer 130, which is located at an upper-most portion of the piezoelectric element 100, no crack is occurred at anywhere in the piezoelectric element 100.

At the same time, the flexible layer 130 can function as a dielectric layer for preventing any unnecessary short-circuit of the electrode pattern 120.

The ceramic cover layer 140, which is coupled to a lower portion of the lower-most ceramic piezoelectric layer 110, can cover and protect the lower-most electrode.

The ceramic cover layer 140 can be made of a same material as the ceramic piezoelectric layer 110. In other words, the ceramic cover layer 140 can include the PNN-PZT ceramic material that is the same for the ceramic piezoelectric layer 110. In such a case, the ceramic cover layer 140 can be made of composition having the following formula as a main component.

x[Pb{Zr_{y}Ti_{(1-y)}}O₃]-(1−x)[Pb(Ni_{z}Nb_{(1-z)}O₃]

Here, like the ceramic piezoelectric layer 110, x, y and z can be 0.8, 0.44 and ⅓, respectively.

Moreover, the ceramic cover layer 140 can further include a secondary component that is used for a sintering aid. The sintering aid used as the secondary component can include at least one of NiO, CuO, ZnO and PbO.

By forming the ceramic cover layer 140 with the same material as the ceramic piezoelectric layer 110, the ceramic piezoelectric layer 110 and the ceramic cover layer 140 can be readily produced without using different materials.

In the case where the ceramic cover layer 140 is coupled to the ceramic piezoelectric layer 110, the adhesive material 12 can be interposed between the ceramic cover layer 140 and the vibrating plate 11.

The ceramic cover layer 140 can be thinner than at least one of the ceramic piezoelectric layers 110. When a single ceramic piezoelectric layer 110 is about 80 um thick, the ceramic cover layer 140 can have a thickness of about 30 um.

Since the ceramic cover layer 140 has no piezoelectric characteristics therein, it is not necessary that the ceramic cover layer 140 has a same thickness as that of one ceramic piezoelectric layer 110, and costs can be saved by forming the ceramic cover layer 140 with a minimum thickness for protecting the electrodes.

A lower-most portion of the piezoelectric element 100 has less stress than the upper-most portion thereof, and is relatively less likely to have a crack occurred therein despite vibrations of the piezoelectric vibrator 10. Therefore, even though the ceramic cover layer 140 made of a ceramic material is used for protecting the lower-most electrode, no crack is occurred.

That is, by using the flexible layer 130, which has no crack occurred therein, for the upper-most portion of the piezoelectric element 100, which has a high possibility of a crack occurred therein, and by using the ceramic cover layer 140, which is reliable for protecting the electrodes, for the lower-most portion of the piezoelectric element 100, which has a low possibility of a crack occurred therein, it becomes possible to protect the electrodes and reduce the occurrence of a crack at the same time.

Referring to FIG. 2, the via 123 can electrically connect the electrodes 121, 122 of the electrode pattern 120 that are arranged side by side. The via 123 can be formed by penetrating the plurality of ceramic piezoelectric layers 110. The via 123 can be classified into a via 123a for connecting the first electrodes 121 and a via 123b for connecting the second electrodes 122.

By using the via 123, the plurality of electrodes that are formed on different layers from one another can be readily connected electrically, making it easier to manufacture the piezoelectric element 100 and prevent any unnecessary short-circuit.

Referring to FIG. 3, the terminals 124, 125 are formed on a surface of the upper-most ceramic piezoelectric layer 110 of the piezoelectric element 100 so as to be exposed, and are connected to an external power source.

The terminals 124, 125 can include a first terminal 124, which is electrically connected with the first electrode 121, and a second terminal 125, which is electrically connected with the second electrode 122. The terminals 124, 125 can be formed to be in direct contact with the via or in direct contact with the terminals.

In the case of a two-terminal configuration, as shown in FIG. 3, both of the terminals 124, 125 can be adjacently disposed on one side of the upper-most ceramic piezoelectric layer 110 to be readily connected with the external power source. In addition, the flexible layer 130 covers the surface of the ceramic piezoelectric layer 110 in such a way that both of the terminals 124, 125 are exposed.

FIG. 6 shows a piezoelectric vibrator in accordance with another embodiment of the present invention, and FIG. 7 shows a piezoelectric element in accordance with another embodiment of the present invention.

Referring to FIG. 6 and FIG. 7, a piezoelectric element 10 in accordance with another embodiment of the present invention can have a four-terminal configuration. In the case of the four-terminal configuration, the numbers of vias 123 and terminals 124, 125 are different from those of an embodiment of the present invention.

There are a total of 4 terminals 124, 125, among which two terminals 124 are connected with first electrodes 121 and the remaining two terminals 125 are connected with second electrodes 122. Meanwhile, there are a total of 4 vias 123, among which two vias 123a are connected with the first electrodes 121 and first terminals 124 and the remaining two vias 123b are connected with the second electrodes 122 and second terminals 125.

Moreover, in the case of the four-terminal configuration, the terminals 124, 125 can be disposed on both sides, as shown in FIG. 7. As such, the number of terminals 124, 125 can vary for different products, as necessary, in order to facilitate the connection with the external power source.

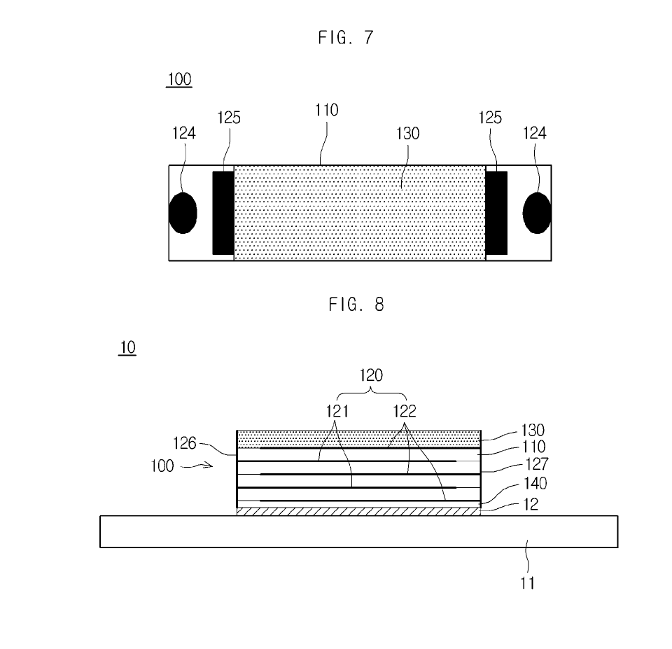

FIG. 8 shows a piezoelectric vibrator in accordance with yet another embodiment of the present invention.

Referring to FIG. 8, a piezoelectric element 100 of a piezoelectric vibrator 10 in accordance with yet another embodiment of the present invention can have external electrodes 126, 127 that substitute vias and terminals. The external electrodes 126, 127 can be configured with a first external electrode 126, which is connected with first electrodes 121, and a second external electrode 127, which is connected with second electrodes 122. The external electrodes 126, 127 can be disposed on lateral surfaces of the piezoelectric element 100 and cover lateral surfaces of a ceramic piezoelectric layer 110.

As described above, with the piezoelectric element and the piezoelectric vibrator having the piezoelectric element in accordance with certain embodiments of the present invention, not only can the electrodes be protected by the flexible layer, but the possibility of a crack occurred in the piezoelectric element and the piezoelectric vibrator can be significantly reduced when the piezoelectric vibrator vibrates.

Although certain embodiments of the present invention have been described, it shall be appreciated that a number of permutations and modifications of the present invention are possible by those who are ordinarily skilled in the art to which the present invention pertains by supplementing, modifying, deleting and/or adding some elements without departing from the technical ideas of the present invention that are disclosed in the claims appended below and that such permutations and modifications are also covered by the scope of the present invention.

What is claimed is:

1. A piezoelectric vibrator comprising:
a vibrating plate; and
a piezoelectric element coupled to an upper surface of the vibrating plate and configured to vibrate the vibrating plate,
wherein the piezoelectric element comprises:
a plurality of ceramic piezoelectric layers configured to contract and expand according to supply of electric power;
an electrode pattern constituted with electrodes laminated alternately with the plurality of ceramic piezoelectric layers; and
a flexible layer formed on a surface of an upper-most electrode of the electrode pattern.

2. The piezoelectric vibrator of claim 1, wherein a thickness of the flexible layer is greater than or equal to ¼ and smaller or equal to ⅓ of a thickness of the piezoelectric element.

3. The piezoelectric vibrator of claim 1, wherein the flexible layer is made of a material comprising resin.

4. The piezoelectric vibrator of claim 1, further comprising a ceramic cover layer coupled to a lower portion of a lower-most layer of the plurality of ceramic piezoelectric layers and covering a lower-most electrode of the electrode pattern.

5. The piezoelectric vibrator of claim 1, further comprising an adhesive material interposed between the piezoelectric element and the vibrating plate.

6. The piezoelectric vibrator of claim 1, wherein the plurality of ceramic piezoelectric layers comprise a PNN-PZT ceramic material.

7. The piezoelectric vibrator of claim 6, wherein the plurality of ceramic piezoelectric layers further comprise a sintering aid comprising at least one of NiO, CuO, ZnO and PbO.

8. The piezoelectric vibrator of claim 1, wherein the electrodes of the electrode pattern comprise at least one of Cu, Ag and Pd.

9. The piezoelectric vibrator of claim 1, wherein the piezoelectric element further comprises a via formed by penetrating the plurality of ceramic piezoelectric layers in order to electrically connect the electrodes of the electrode pattern.

10. The piezoelectric vibrator of claim 9, wherein the piezoelectric element further comprises a terminal electrically connected with the electrode pattern and formed to be exposed on a surface of an upper-most layer of the plurality of ceramic piezoelectric layers.

11. The piezoelectric vibrator of claim 10, wherein the via and the terminal are each provided in two pairs that are electrically connected with the electrodes.

12. The piezoelectric vibrator of claim 1, further comprising an external electrode formed on lateral surfaces of the plurality of ceramic piezoelectric layers so as to electrically connect the electrodes of the electrode pattern.

13. A piezoelectric element comprising:
a plurality of ceramic piezoelectric layers configured to contract and expand according to supply of electric power;
an electrode pattern constituted with electrodes laminated alternately with the plurality of ceramic piezoelectric layers; and
a flexible layer formed on a surface of an upper-most electrode of the electrode pattern.

14. The piezoelectric element of claim 13, wherein a thickness of the flexible layer is greater than or equal to ¼ and smaller or equal to ⅓ of a thickness of the piezoelectric element.

15. The piezoelectric element of claim 13, wherein the flexible layer is made of a material comprising resin.

16. The piezoelectric element of claim 13, further comprising a ceramic cover layer coupled to a lower portion of a lower-most layer of the plurality of ceramic piezoelectric layers and covering a lower-most electrode of the electrode pattern.

17. The piezoelectric element of claim 13, wherein the plurality of ceramic piezoelectric layers further comprise a PNN-PZT ceramic material and a sintering aid comprising at least one of NiO, CuO, ZnO and PbO.

18. The piezoelectric element of claim 13, further comprising a via formed by penetrating the plurality of ceramic piezoelectric layers in order to electrically connect the electrodes of the electrode pattern.

19. The piezoelectric element of claim 18, further comprising a terminal electrically connected with the electrode pattern and formed to be exposed on a surface of an upper-most layer of the plurality of ceramic piezoelectric layers.

20. The piezoelectric element of claim 19, wherein the via and the terminal are each provided in two pairs that are electrically connected with the electrodes.

21. The piezoelectric element of claim 13, further comprising an external electrode formed on lateral surfaces of the plurality of ceramic piezoelectric layers so as to electrically connect the electrodes of the electrode pattern.
